(19) United States
(12) Patent Application Publication
(10) Pub. No.: US 2026/0316125 A1
(43) Pub. Date: Oct. 15, 2026

(54) SUBSTRATE PROCESSING METHOD AND SUBSTRATE PROCESSING APPARATUS

(71) Applicant: Tokyo Electron Limited, Tokyo (JP)

(72) Inventors: Rintaro HIGUCHI, Kumamoto (JP); Koji KAGAWA, Kumamoto (JP)

(21) Appl. No.: 19/467,005

(22) Filed: Feb. 2, 2026

(30) Foreign Application Priority Data
Feb. 13, 2025 (JP) 2025-021631

(51) Int. Cl. B08B 7/04; B08B 3/04; B08B 3/08; B08B 13/00; C11D 7/04; H10P 70/00

(52) U.S. Cl. CPC B08B 7/04; B08B 3/041; B08B 3/08; B08B 13/00; C11D 7/04; H10P 70/27

(57) ABSTRACT

A substrate processing method includes: a first process of supplying, to a substrate including a stacked film constituted by a polysilicon film and a metal film stacked adjacent to the polysilicon film, a hydrogen-dissolved chemical liquid in which hydrogen is dissolved in a chemical liquid, wherein an energy level of the hydrogen-dissolved chemical liquid is higher than that of the metal film; and a second process of supplying hydrogen water to the substrate after the first process.

### CROSS-REFERENCE TO RELATED APPLICATION

This application is based upon and claims the benefit of priority from Japanese Patent Application No. 2025-021631, filed on Feb. 13, 2025, the entire content of which is incorporated herein by reference.

### TECHNICAL FIELD

The present disclosure relates to a substrate processing method and a substrate processing apparatus.

### BACKGROUND

Patent Document 1 discloses a method of cleaning a substrate formed with a circuit, in which pH of pure water or ultra-pure water is adjusted to 8.5 or more and less than 9.5, and the substrate is cleaned by applying physical actions using alkaline hydrogen water in which a hydrogen gas is dissolved.

### PRIOR ART DOCUMENT

### Patent Document

Patent Document 1: Japanese Laid-open Patent Publication No. 2019-179813

### SUMMARY

A substrate processing method according to the present disclosure includes: a first process of supplying, to a substrate including a stacked film constituted by a polysilicon film and a metal film stacked adjacent to the polysilicon film, a hydrogen-dissolved chemical liquid in which hydrogen is dissolved in a chemical liquid, wherein an energy level of the hydrogen-dissolved chemical liquid is higher than an energy level of the metal film; and a second process of supplying hydrogen water to the substrate after the first process.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view schematically illustrating an example of a substrate processing system.

FIG. 2 is a cross-sectional view illustrating an example of a substrate.

FIG. 3 is a diagram schematically illustrating an example of a liquid processing unit.

FIG. 4 is a block diagram illustrating an example of major components of the substrate processing system.

FIG. 5 is a schematic diagram illustrating an example of a hardware configuration of a controller.

FIG. 6 is a flowchart illustrating an example of substrate processing.

FIGS. 7A to 7D are diagrams illustrating an example of the substrate processing.

FIG. 8 is a cross-sectional view illustrating an example of the substrate for explaining how polysilicon is corroded.

FIG. 9 is a diagram for explaining a movement of electrons when a chemical liquid alone is supplied to the substrate.

FIG. 10 is a diagram for explaining a movements of electrons when a hydrogen-dissolved chemical liquid is supplied to the substrate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the following description, same elements or elements having the same functions are designated by same reference numerals, and redundant descriptions thereof will be omitted. In addition, in this specification, when referring to up, down, right, and left in the drawings, directions of the reference numerals in the drawings are used as a reference.

### Substrate Processing System

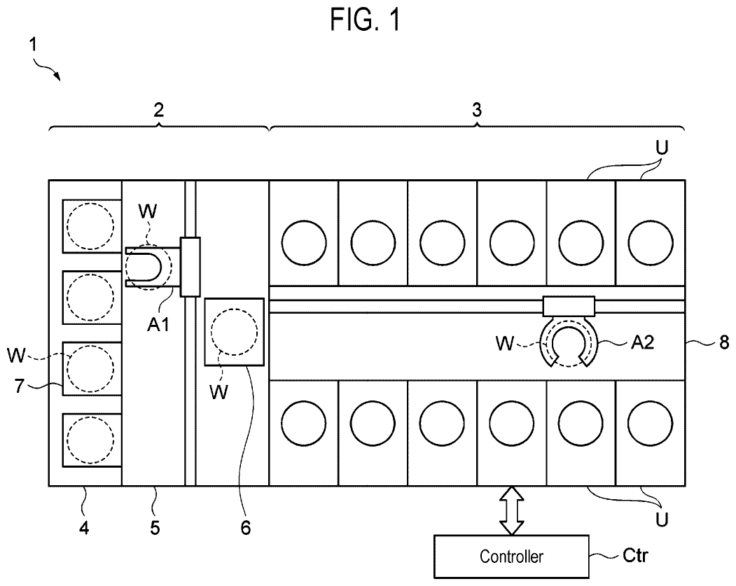

First, a substrate processing system 1 (substrate processing apparatus) configured to process a substrate W will be described with reference to FIG. 1. The substrate processing system 1 includes a loading/unloading station 2, a processing station 3, and a controller Ctr. The loading/unloading station 2 and the processing station 3 may be arranged in a row in, for example, a horizontal direction.

The substrate W may have a disk shape, or may have a plate shape such as a polygonal shape other than circular. The substrate W may also have a cutout at which a portion of the substrate W is cut out. The cutout may be, for example, a notch (a U-shaped or V-shaped groove), or may be a linear portion (a so-called “orientation flat”) extending linearly. The substrate W may be, for example, a semiconductor substrate (silicon wafer), a glass substrate, a mask substrate, a flat panel display (FPD) substrate, or various other types of substrates. A diameter of the substrate W may be, for example, approximately 200 mm to 450 mm.

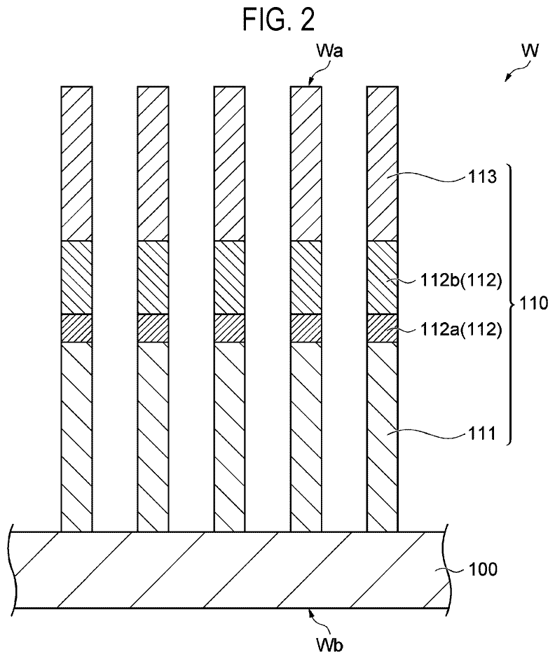

As illustrated in FIG. 2, the substrate W includes a base 100 and a stacked film 110. The base 100 may be, for example, a silicon wafer, or may have at least one film formed on an upper surface of the silicon wafer.

The stacked film 110 may have a predetermined patterned shape. The stacked film 110 includes at least a polysilicon film 111 and a metal film 112 stacked adjacent to the polysilicon film 111. In an example of FIG. 2, the stacked film 110 includes, the polysilicon film 111, the metal film 112, and an insulating film 113, which are provided sequentially from the base 100. The metal film 112 may be constituted with a single metal film, or a plurality of metal films. In the example of FIG. 2, the metal film 112 may be constituted with two metal films 112a and 112b provided sequentially from the base 100.

The metal film 112 may be formed of, for example, titanium nitride (TiN), titanium silicon nitride (TiSiN), tungsten (W), molybdenum (Mo), or the like. That is, the metal film 112, which is brought into direct contact with the polysilicon film 111, may be formed of titanium nitride, titanium silicon nitride, tungsten, molybdenum, or the like. In the example of FIG. 2, the metal film 112a may be formed of titanium nitride, and the metal film 112b may be formed of tungsten. In this specification, an energy level of the metal film 112 is defined by a work function (minimum energy required to extract one electron from a surface of a substance to infinity). The insulating film 113 may be formed of, for example, silicon nitride (SiN).

In this specification, an upper surface Wa of the substrate W refers to an upper surface of an element located at the uppermost position among all elements constituting the substrate W. That is, as illustrated in FIG. 2, when the substrate W is constituted with, for example, the base 100, the metal film 112, and the insulating film 113, the upper surface Wa of the substrate W refers to an upper surface of the insulating film 113. When the substrate W is constituted with, for example, the base 100 and the metal film 112, the upper surface Wa of the substrate W refers to an upper surface of the metal film 112.

Returning to FIG. 1, the loading/unloading station 2 includes a stage part 4, a loader/unloader 5, and a shelf unit 6. The stage part 4 includes a plurality of stages (not illustrated) arranged in a width direction (an up-down direction in FIG. 1). Each stage is configured to place a carrier 7 thereon. The carrier 7 is configured to accommodate at least one substrate W in a sealed state. The carrier 7 includes an opening/closing door (not illustrated) for loading and unloading the substrate W therethrough.

The loader/unloader 5 is disposed to be adjacent to the stage part 4 in a direction in which the loading/unloading station 2 and the processing station 3 are aligned (a left-right direction in FIG. 1). The loader/unloader 5 includes an opening/closing door (not illustrated) provided for the stage part 4. When both the opening/closing door of the carrier 7 and the opening/closing door of the loader/unloader 5 are open in a state in which the carrier 7 is placed on the stage part 4, an interior of the loader/unloader 5 and an interior of the carrier 7 are brought into communication with each other.

The loader/unloader 5 incorporates a transfer arm Al and the shelf unit 6. The transfer arm Al is configured to be movable in a width direction of the loader/unloader 5, movable upward and downward in a vertical direction of the loader/unloader 5, and rotatable about a vertical axis, based on signals from the controller Ctr. The transfer arm Al is configured to take out the substrate W from the carrier 7 and deliver the same to the shelf unit 6, and also to receive the substrate W from the shelf unit 6 and return the same into the carrier 7. The shelf unit 6 is located in a vicinity of the processing station 3 and is configured to accommodate the substrate W.

The processing station 3 includes a transferrer 8 and a plurality of liquid processing units U. The transferrer 8 extends horizontally, for example, in the direction in which the loading/unloading station 2 and the processing station 3 are aligned (the left-right direction in FIG. 1). The transferrer 8 incorporates a transfer arm A2 (transferrer). The transfer arm A2 is configured to be movable horizontally in a longitudinal direction of the transferrer 8, movable upward and downward in the vertical direction of the transferrer 8, and rotatable about a vertical axis, based on signals from the controller Ctr. The transfer arm A2 is configured to take out the substrate W from the shelf unit 6 and deliver the same to the liquid processing unit U, and also to receive the substrate W from the liquid processing unit U and return the same into the shelf unit 6.

The plurality of liquid processing units U are disposed in a row along the longitudinal direction of the transferrer 8 (the left-right direction in FIG. 1) on both sides of the transferrer 8. A configuration of the liquid processing unit U will be described later.

The controller Ctr, as will be described in detail later, is configured to control the substrate processing system 1 partially or entirely.

### Liquid Processing Unit

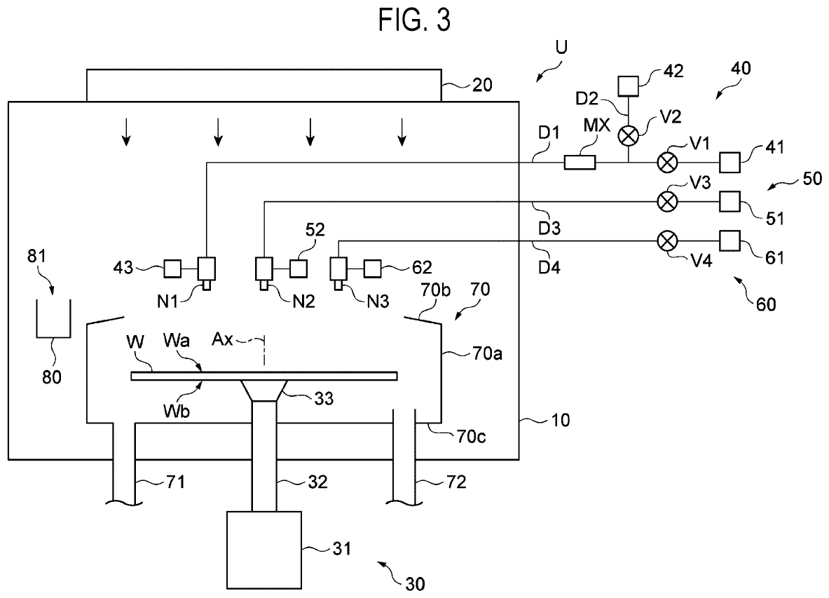

Next, the liquid processing unit U will be described in detail with reference to FIG. 3. The liquid processing unit U is configured to perform predetermined liquid processing (for example, removal of contaminants or foreign matters) on the substrate W. The liquid processing unit U may be, for example, a single-wafer-type cleaning apparatus that cleans the substrates W one by one by spin cleaning.

The liquid processing unit U includes a housing 10, a blower 20, a rotary holder 30, a supplier 40 (first supplier), a supplier 50 (second supplier), a supplier 60 (third supplier), a cup 70, and a liquid receiver 80.

The rotary holder 30 is accommodated in an interior of the housing 10. The housing 10 is configured so that the substrate W can be loaded into and unloaded from the interior of the housing 10. A loading/unloading port (not illustrated) is formed in a sidewall of the housing 10. The substrate W is transferred to the interior of the housing 10 and is unloaded from the housing 10 to the outside via the loading/unloading port by the transfer arm A2.

The blower 20 is attached to a ceiling wall of the housing 10. The blower 20 is configured to form a down-flow in the interior of the housing 10 based on signals from the controller Ctr. The down-flow formed by the blower 20 flows toward the upper surface Wa of the substrate W held by the rotary holder 30.

The rotary holder 30 includes a drive 31, a shaft 32, and a holder 33. The drive 31 is configured to operate based on control signals from the controller Ctr to rotate the shaft 32. The drive 31 may be, for example, a power source such as an electric motor.

The holder 33 is provided at a tip end of the shaft 32. The holder 33 is configured to hold a back surface Wb of the substrate W by, for example, attraction. That is, the rotary holder 30 may be configured to rotate the substrate W around a rotational central axis Ax perpendicular to the upper surface Wa of the substrate W, with the substrate W being kept in a substantially horizontal posture. In addition, instead of the attraction, the holder 33 may be configured to hold the substrate W by clamping a peripheral edge portion of the substrate W by a plurality of movable members.

The supplier 40 includes supply units 41 and 42, valves V1 and V2, a mixer MX, a drive 43, and a nozzle N1. The supply unit 41 functions as a source of a chemical liquid. That is, the supply unit 41 is configured to feed the chemical liquid to the nozzle N1 via a pipe D1.

The chemical liquid may be, for example, an acidic chemical liquid or an alkaline chemical liquid. Examples of the acid chemical liquid may include an SC-2 liquid (a mixed liquid of hydrochloric acid, hydrogen peroxide, and pure water), an SPM liquid (a mixed liquid of sulfuric acid and hydrogen peroxide water), an HF liquid (hydrofluoric acid), a DHF liquid (dilute hydrofluoric acid), and an HNO₃+HF liquid (a mixed liquid of nitric acid and hydrofluoric acid). Examples of the alkaline chemical liquid may include an SC-1 liquid (a mixed liquid of ammonia, hydrogen peroxide, and pure water), and hydrogen peroxide water.

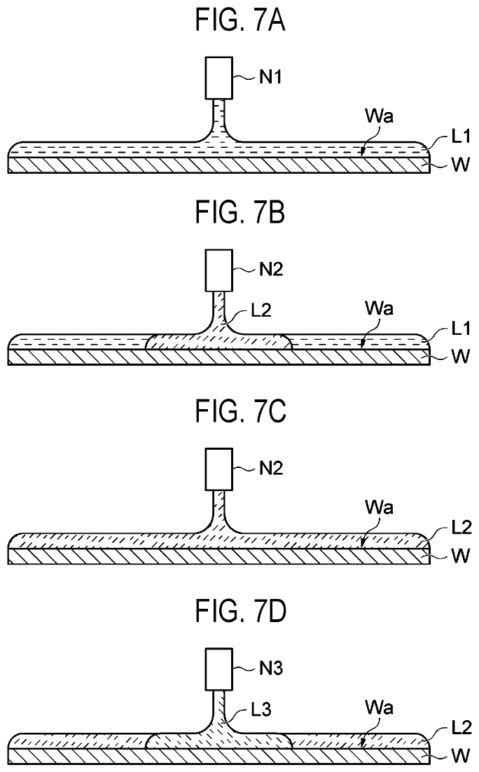

The supply unit 42 functions as a source of hydrogen water L2 (see FIGS. 7A to 7D). That is, the supply unit 42 is configured to supply the hydrogen water L2 to the pipe D1 via a pipe D2. A downstream end of the pipe D2 is connected to the pipe D1. The hydrogen water L2 may be generated by, for example, mixing a hydrogen gas obtained by electrolyzing water with water using a gas-liquid mixer. The water mixed with the hydrogen gas may be the same as a cleaning liquid L3 to be described later. A concentration of hydrogen in the hydrogen water L2 may be, for example, 1 ppm or more, or may be a saturation concentration (approximately 1.6 ppm).

The valve V1 is provided on an upstream side of a connection portion between the pipes D1 and D2 in the pipe D1. The valve V2 is provided at the pipe D2. The valves V1 and V2 are configured to be open and closed based on control signals from the controller Ctr. An opening degree of each valve V1 or V2 may be changed, for example, in a stepwise manner, or a continuous manner such that the opening degree reaches a predetermined level.

The mixer MX is provided on a downstream side of the connection portion between the pipes D1 and D2 in the pipe D1. The mixer MX is configured to mix the chemical liquid supplied from the supply unit 41 with the hydrogen water L2 supplied from the supply unit 42, thereby generating a hydrogen-dissolved chemical liquid L1 (see FIGS. 7A to 7D). An energy level of the hydrogen-dissolved chemical liquid L1 is higher than that of the metal film 112. In this specification, the energy level of the hydrogen-dissolved chemical liquid L1 is defined by oxidation-reduction potential (ORP). A concentration of hydrogen in the hydrogen-dissolved chemical liquid L1 may be, for example, 1 ppm or more, or may be a saturation concentration (approximately 1.6 ppm).

When the chemical liquid and the hydrogen water L2 are supplied from the supply units 41 and 42, respectively, the hydrogen-dissolved chemical liquid L1 generated in the mixer MX reaches the nozzle N1 via the pipe D1 and is discharged from the nozzle N1. On the other hand, when only the chemical liquid is supplied from the supply unit 41, the chemical liquid reaches the nozzle N1 via the pipe D1 and is discharged from the nozzle N1.

The drive 43 is configured to operate move the nozzle N1 horizontally or vertically based on control signals from the controller Ctr. The drive 43 may be configured to move the nozzle N1, for example, between a position above the substrate W held by the rotary holder 30 and a position outside of the substrate W held by the rotary holder 30 (for example, outside of the cup 70).

The supplier 50 includes a supply unit 51, a valve V3, a drive 52, and a nozzle N2. The supply unit 51 functions as a source of hydrogen water L2 just like the supply unit 42. That is, the supply unit 51 is configured to deliver the hydrogen water L2 to the nozzle N2 via a pipe D3. A concentration of hydrogen in the hydrogen water L2 supplied from the supply unit 51 may be substantially equal to the concentration of hydrogen in the hydrogen water L2 supplied from the supply unit 42. In addition, the hydrogen water L2 supplied from the supply unit 42 instead of the supply unit 51, may be supplied to the pipe D3.

The valve V3 is provided in the pipe D3. The valve V3 is configured to be open and closed based on control signals from the controller Ctr. An opening degree of the valve V3 may be changed, for example, in a stepwise manner, or in a continuous manner such that the opening degree reaches a predetermined level.

The drive 52 is configured to operate move the nozzle N2 horizontally or vertically based on control signals from the controller Ctr. The drive 52 may be configured to move the nozzle N2, for example, between a position above the substrate W held by the rotary holder 30 and a position outside of the substrate W held by the rotary holder 30 (for example, outside of the cup 70).

The supplier 60 includes a supply unit 61, a valve V4, a drive 62, and a nozzle N3. The supply unit 61 functions as a source of the cleaning liquid L3. That is, the supply unit 61 is configured to feed the cleaning liquid L3 to the nozzle N3 via a pipe D4. The cleaning liquid L3 fed from the supply unit 61 is supplied from the nozzle N3 to the upper surface Wa of the substrate W. The cleaning liquid L3 may include, for example, deionized water (DIW), ozone water, carbonated water (CO₂ water), ammonia water or the like. In addition, in this specification, the hydrogen-dissolved chemical liquid L1, the hydrogen water L2, and the cleaning liquid L3 may collectively be referred to as “processing liquid”.

The valve V4 is provided in the pipe D4. The valve V4 is configured to be open and closed based on control signals from the controller Ctr. An opening degree of the valve V4 may be changed, for example, in a stepwise manner, or in a continuous manner such that the opening degree reaches a predetermined level.

The drive 62 is configured to operate move the nozzle N3 horizontally or vertically based on control signals from the controller Ctr. The drive 62 may be configured to move the nozzle N3, for example, between a position above the substrate W held by the rotary holder 30 and a position outside of the substrate W held by the rotary holder 30 (for example, outside of the cup 70).

The cup 70 is provided to surround a periphery of the holder 33 and a periphery of the substrate W held by the holder 33 from the outside. The cup 70 is configured to collect the processing liquid shaken off from an outer peripheral edge of the substrate W to the surroundings when the processing liquid is supplied to the upper surface Wa of the substrate W which is being rotated by the rotary holder 30.

The cup 70 includes a sidewall portion 70a, a ceiling wall portion 70b, and a bottom wall portion 70c. The sidewall portion 70a has a cylindrical shape as a whole so as to surround the periphery of the holder 33 from the outside. The ceiling wall portion 70b has an annular shape and extends inward from an upper end portion of the sidewall portion 70a. In an example of FIG. 3, the ceiling wall portion 70b extends inward and obliquely upward from the upper end portion of the sidewall portion 70a. The bottom wall portion 70c is provided at a lower end portion of the sidewall portion 70a so as to close the lower end portion.

A drain port 71 and an exhaust port 72 are provided in the bottom wall portion 70c of the cup 70. The drain port 71 is configured to discharge the processing liquid collected by the cup 70 to the outside of the liquid processing unit U. The exhaust port 72 is configured to discharge the down-flow formed at the periphery of the substrate W by the blower 20 to the outside of the liquid processing unit U. The down-flow is accompanied by gases generated at the periphery of the substrate W as the substrate W is processed by the processing liquid.

The liquid receiver 80 is disposed outside of the cup 70. The liquid receiver 80 has an opening 81, which is open upward, to receive the processing liquid discharged from the nozzles N1 and N2.

### Controller

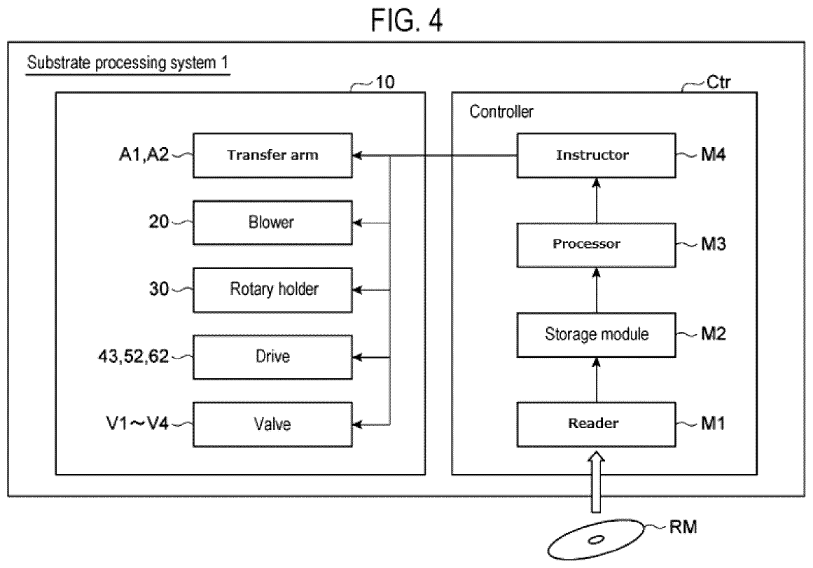

As illustrated in FIG. 4, the controller Ctr includes, as functional modules, a reader M1, a storage M2, a processor M3, and an instructor M4. These functional modules are merely used to distinguish functions of the controller Ctr into a plurality of modules for the sake of convenience in description, which does not necessarily mean that the hardware constituting the controller Ctr is divided into such modules. Each functional module is not limited to being implemented by executing a program, and may also be implemented by a dedicated electric circuit (for example, a logic circuit) or an integrated circuit (for example, an application specific integrated circuit (ASIC)).

The reader MI is configured to read a program from a non-transitory computer-readable recording medium RM (device). The recording medium RM records programs for operating individual components (the transfer arms A1 and A2, the blower 20, the rotary holder 30, the drives 43, 52 and 62, the valves V1 to V4, and the like) of the substrate processing system 1. Examples of the recording medium RM may include a semiconductor memory, an optical recording disk, a magnetic recording disk, and a magneto-optical recording disk. The recording medium RM may be built into the substrate processing system 1, or may be provided separately from the substrate processing system 1.

The storage M2 is configured to store various pieces of data. The storage M2 may store, for example, a program read from the recording medium RM by the reader M1, setting data input by an operator via an external input device (not illustrated), and the like.

The processor M3 is configured to process various pieces of data. The processing section M3 may be configured to generate operation signals for operating individual components of the substrate processing system 1 based on, for example, the various pieces of data stored in the storage M2.

The instructor M4 is configured to transmit the operation signals generated by the processor M3 to individual components of the substrate processing system 1.

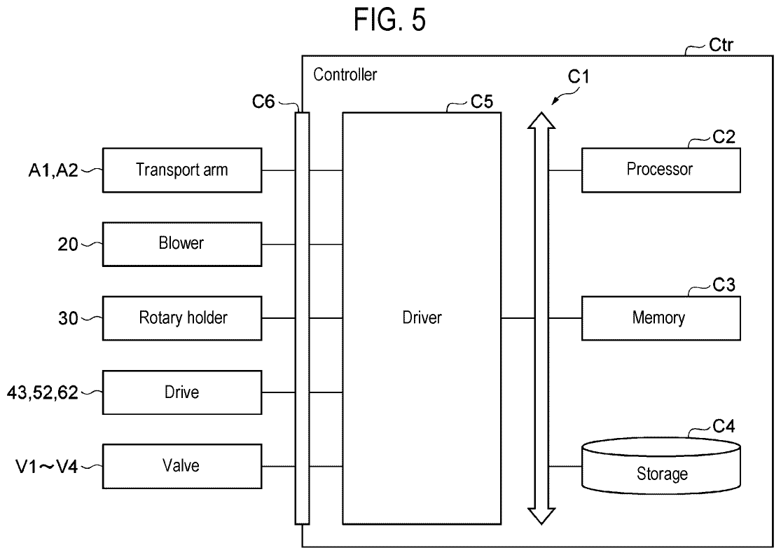

The hardware of the controller Ctr may be constituted with, for example, one or more computers for control. The controller Ctr may include, for example, a circuit C1 illustrated in FIG. 5 as a hardware configuration. The circuit C1 may be constituted with electric circuit elements (circuitry). Examples of the circuit C1 may include a processor C2, a memory C3 (storage), a storage C4, a driver C5, and an input/output port C6. The processor C2 executes a program in cooperation with at least one of the memory C3 or the storage C4, and executes input and output of signals via the input/output port C6, thereby implementing each of the above-described functional modules. The memory C3 and the storage C4 function as the storage M2. The driver C5 is a circuit that drives individual components of the substrate processing system 1. The input/output port C6 performs the input and output of signals between the driver C5 and individual components of the substrate processing system 1.

The substrate processing system 1 may include one controller Ctr, or may include a controller group (controller) constituted with a plurality of controllers Ctr. In the latter case, each of the aforementioned functional modules may be implemented by one controller Ctr or may be implemented by a combination of two or more controllers Ctr. When the controller Ctr is constituted with a plurality of computers (circuits C1), each of the aforementioned functional modules may be implemented by one computer (one circuit C1), or by a combination of two or more computers (two or more circuits C1). The controller Ctr may include a plurality of processors C2. In this case, each of the aforementioned functional modules may be implemented by one processor C2, or may be implemented by a combination of two or more processors C2.

### Substrate Processing Method

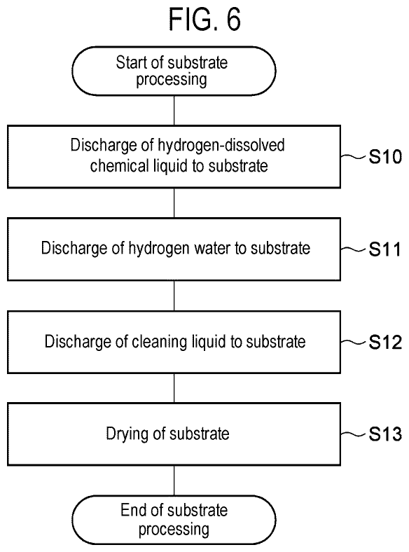

Next, the processing of the substrate W will be described with reference to FIGS. 6 and 7A to 7D. The description will be given on the assumption that, as an initial state, the substrate W is held by the rotary holder 30 and the valves V1 to V4 remain closed.

First, the controller Ctr instructs the rotary holder 30 to rotate the substrate W. Next, the controller Ctr instructs the drive 43 to position the nozzle N1 above the substrate W (for example, above a central portion of the substrate W). Next, while the rotation of the substrate W is continued, the controller Ctr instructs the valves V1 and V2 to be open. Thus, the hydrogen-dissolved chemical liquid L1 is discharged from the nozzle N1 to the upper surface Wa of the substrate W, and liquid processing (for example, removal of contaminants or foreign matters) of the substrate W is performed (see Step S10 in FIG. 6 and FIG. 7A).

Next, after a predetermined period of time t1 has elapsed from the start of the discharge of the hydrogen-dissolved chemical liquid L1 from the nozzle N1, the controller Ctr instructs the valves V1 and V2 to be closed. Thus, the discharge of the hydrogen-dissolved chemical liquid L1 from the nozzle N1 is stopped. The predetermined period of time t1 may be, for example, approximately 10 to 300 seconds. Next, the controller Ctr instructs the drive 43 to move the nozzle N1 to the outside of the substrate W (for example, to the outside of the cup 70).

Next, the controller Ctr instructs the drive 52 to position the nozzle N2 above the substrate W (for example, above the central portion of the substrate W). Next, while the rotation of the substrate W is continued, the controller Ctr instructs the valve V3 to be open. Thus, the hydrogen water L2 is discharged from the nozzle N2 to the upper surface Wa of the substrate W (see Step S11 in FIG. 6 and FIG. 7B). Therefore, the hydrogen-dissolved chemical liquid L1 on the upper surface Wa of the substrate W is washed away from the upper surface Wa of the substrate W by the hydrogen water L2.

Next, after a predetermined period of time t2 has elapsed from the start of the discharge of the hydrogen water L2 from the nozzle N2, the controller Ctr instructs the valve V3 to be closed. Thus, the discharge of the hydrogen water L2 from the nozzle N2 is stopped. At this time, all or almost all of the hydrogen-dissolved chemical liquid L1 is washed away from the upper surface Wa of the substrate W by the hydrogen water L2. Accordingly, the hydrogen water L2 primarily remains on the upper surface Wa of the substrate W (see FIG. 7C). The predetermined period of time t2 may be, for example, a period of time sufficient for the hydrogen water L2 to wash away all or almost all of the hydrogen-dissolved chemical liquid L1 from the upper surface Wa of the substrate W. The predetermined period of time t2 may be, for example, approximately 30 to 120 seconds. Next, the controller Ctr instructs the drive 52 to move the nozzle N2 to the outside of the substrate W (for example, to the outside of the cup 70).

Next, the controller Ctr instructs the drive 62 to position the nozzle N3 above the substrate W (for example, above the central portion of the substrate W). Next, while the rotation of the substrate W is continued, the controller Ctr instructs the valve V4 to be open. Thus, the cleaning liquid L3 is discharged from the nozzle N3 to the upper surface Wa of the substrate W (see Step S12 in FIG. 6 and FIG. 7D). Therefore, the hydrogen water L2 on the upper surface Wa of the substrate W is washed away from the upper surface Wa of the substrate W by the cleaning liquid L3.

Next, after a predetermined period of time t3 has elapsed from the start of the discharge of the cleaning liquid L3 from the nozzle N3, the controller Ctr instructs the valve V4 to be closed. Thus, the discharge of the cleaning liquid L3 from the nozzle N3 is stopped. At this time, all or almost all of the hydrogen water L2 is washed away from the upper surface Wa of the substrate W by the cleaning liquid L3. The predetermined period of time t3 may be, for example, a period of time sufficient for the cleaning liquid L3 to wash away all or almost all of the hydrogen water L2 from the upper surface Wa of the substrate W. The predetermined period time t3 may be, for example, approximately 60 to 180 seconds. Next, the controller Ctr instructs the drive 62 to move the nozzle N3 to the outside of the substrate W (for example, to the outside of the cup 70). After the supply of the cleaning liquid L3 to the substrate W, an organic solvent (for example, isopropyl alcohol (IPA)) may be supplied to the substrate W.

Next, the controller Ctr instructs the rotary holder 30 to continue the rotation of the substrate W for a predetermined period of time t4 after the stop of discharge of the cleaning liquid L3 from the nozzle N3. Thus, the cleaning liquid L3 on the upper surface Wa of the substrate W is dropped off from the outer peripheral edge of the substrate W, thereby drying the substrate W (see Step S13 in FIG. 6). In this way, the processing of the substrate W is terminated.

### Operations

When a pattern formation process is performed by performing the dry etching on the substrate W including the polysilicon film 111, polymer residues may adhere to the substrate W. Therefore, the substrate W is processed with a chemical liquid to remove such residues.

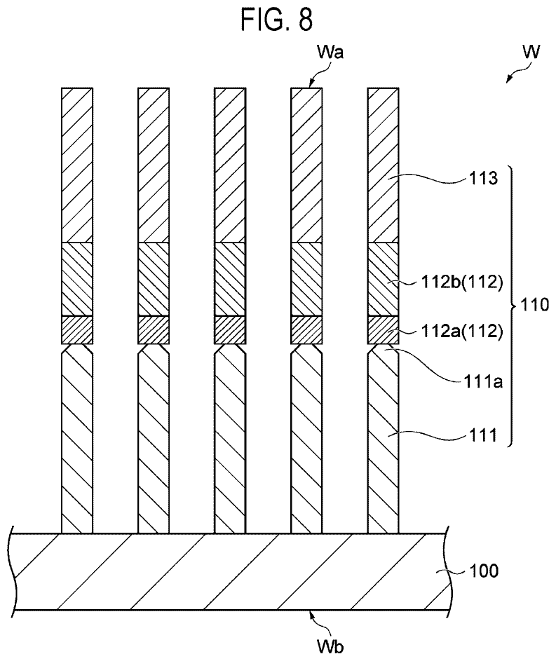

However, the present inventors have found that, in a case of supplying the chemical liquid alone to the substrate W including the stacked film 110 constituted with the polysilicon film 111 and the metal film 112 stacked adjacent to the polysilicon film 111, as illustrated in FIG. 8, corrosion may occur in a portion 111a of the polysilicon film 111 in a vicinity of a surface bonded to the metal film 112. When the corrosion occurs, the corroded portion 111a of the polysilicon film 111 may be narrowed, which may affect electrical characteristics. Further, when the substrate W including the polysilicon film 111 is used as an electronic device as a final product, current leakage or defective contact may occur in the corroded portion 111a.

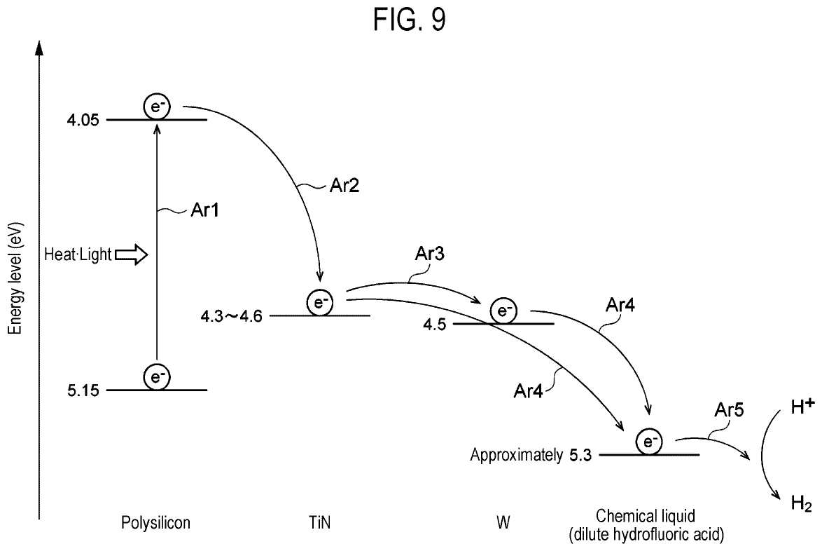

The present inventors conducted research over and over and found that the corrosion of the polysilicon film 111 occurs because the energy level of the chemical liquid is lower than the energy level of the metal film 112. This will be described with reference to FIG. 9. Silicon has a relatively small bandgap (approximately 1.1 eV), and electrons in a valence band may be easily excited and transitioned to a conduction band (see arrow Ar1 in FIG. 9) by heat at approximately room temperature or by light such as visible light. On the other hand, since an energy level of the metal film 112a (titanium nitride) bonded to the polysilicon film is lower than an energy level of the conduction band, the electrons that have transitioned to the conduction band move to the metal film 112a (see arrow Ar2 in FIG. 9). Further, since an energy level of the metal film 112b (tungsten) bonded to the metal film 112a is lower than the energy level of the metal film 112a, the electrons of the metal film 112a may move to the metal film 112b (see arrow Ar3 in FIG. 9).

Further, since the energy level of the chemical liquid (for example, dilute hydrofluoric acid) is lower than the energy levels of the metal films 112a and 112b, the electrons of the metal films 112a and 112b move to the chemical liquid (see arrow Ar4 in FIG. 9). The electrons that have moved to the chemical liquid are consumed in the reduction of hydrogen ions (H⁺) in the solvent water (H₂O) of the chemical liquid (see arrow Ar5 in FIG. 9), thereby generating hydrogen (H₂). In this way, the electrons of silicon move to the chemical liquid via the metal film 112 so that the electrons are removed from silicon. In the corroded portion 111a of silicon from which the electrons have been removed, the silicon becomes an oxidize and is etched by the chemical liquid (see FIG. 8). By such a mechanism, the corrosion of the polysilicon film 111 occurs.

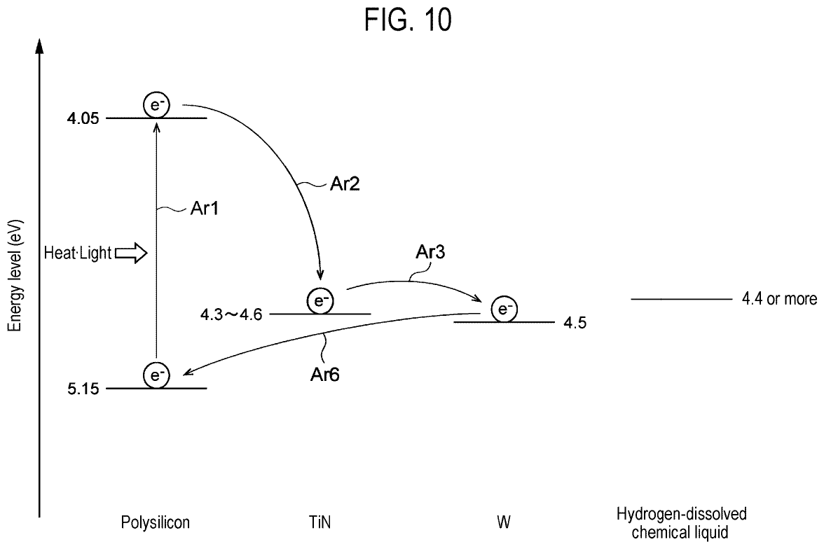

In the above-described example, the hydrogen-dissolved chemical liquid L1 having a higher energy level than the metal film 112 is supplied to the substrate W. Therefore, the electrons that have moved from the conduction band of silicon to the metal film 112 are less likely to move to the hydrogen-dissolved chemical liquid L1. Accordingly, as illustrated in FIG. 10, the electrons that have not been consumed in the reduction of hydrogen ions return to the valence band of silicon (see arrow Ar6 in FIG. 10). Therefore, the oxidation of silicon is less likely to occur.

Further, in the above-described example, after the hydrogen-dissolved chemical liquid L1 is supplied to the substrate W, the hydrogen water L2 is supplied to the substrate W. Thus, the hydrogen water L2 is supplied to the hydrogen-dissolved chemical liquid L1 remaining on the upper surface Wa of the substrate W. Therefore, when the hydrogen-dissolved chemical liquid L1 and the hydrogen water L2 are mixed with each other on the upper surface Wa of the substrate W, a concentration of hydrogen in a resulting mixed liquid is less likely to decrease. Accordingly, an energy level of the mixed liquid is less likely to be lower than the energy level of the metal film 112. Therefore, the hydrogen-dissolved chemical liquid L1 remaining on the upper surface Wa of the substrate W is washed away by the hydrogen water L2 while the oxidation of silicon by the mixed liquid is suppressed.

From the foregoing, it becomes possible to suppress the corrosion of the polysilicon film 111.

In the above-described example, the concentration of hydrogen in the hydrogen-dissolved chemical liquid L1 may be 1 ppm or more. In this case, the energy level of the hydrogen-dissolved chemical liquid L1 tends to be higher than that of the metal film 112. Therefore, it becomes possible to further suppress the corrosion of the polysilicon film 111.

In the above-described example, the concentration of hydrogen in the hydrogen-dissolved chemical liquid L1 may be a saturation concentration. In this case, the energy level of the hydrogen-dissolved chemical liquid L1 tends to be further higher than that of the metal film 112. Therefore, it becomes possible to further suppress the corrosion of the polysilicon film 111.

In the above-described example, after the hydrogen water L2 is supplied to the substrate W, the cleaning liquid L3 is supplied to the substrate W. Thus, after the hydrogen-dissolved chemical liquid L1 is washed away by the hydrogen water L2, the cleaning liquid L3 is supplied to the substrate W. Accordingly, in a state where the hydrogen-dissolved chemical liquid L1 hardly remains on the upper surface Wa of the substrate W, the cleaning liquid L3 is supplied to the upper surface Wa of the substrate W. Thus, even if the hydrogen water L2 and the cleaning liquid L3 are mixed with each other on the upper surface Wa of the substrate W and the concentration of hydrogen in the mixed liquid decreases, the oxidation of silicon hardly occurs. Therefore, it becomes possible to suppress the corrosion of the polysilicon film 111 caused by supplying the cleaning liquid L3 to the substrate W. Further,, since the substrate W is cleaned by the cleaning liquid L3, an amount of the hydrogen water L2 supplied during the process of supplying the hydrogen water L2 to the substrate W may be set to a level sufficient to wash away the hydrogen-dissolved chemical liquid L1 remaining on the upper surface Wa of the substrate W. Therefore, the amount of the hydrogen water L2 used can be reduced, making it possible to reduce the cost of the substrate processing.

In the above-described example, the chemical liquid and the hydrogen water L2 are respectively supplied from the supply units 41 and 42 and are mixed with each other in the mixer MX to generate the hydrogen-dissolved chemical liquid L1. Thereafter, the hydrogen-dissolved chemical liquid L1 is supplied to the upper surface Wa of the substrate W. In this case, the hydrogen water L2 is mixed with the hydrogen-dissolved chemical liquid L1 immediately before the hydrogen-dissolved chemical liquid L1 is supplied. Therefore, the concentration of hydrogen in the hydrogen-dissolved chemical liquid L1 hardly decreases until the hydrogen-dissolved chemical liquid L1 is supplied to the substrate W. Accordingly, it becomes possible to further suppress the corrosion of the polysilicon film 111.

### Modifications

It should be noted that the disclosure in this specification is exemplary in all respects and is not restrictive. Various omissions, substitutions, changes, and the like may be made to the above-described examples without departing from the scope and spirit of the appended claims.

Before supplying the hydrogen-dissolved chemical liquid L1 to the upper surface Wa of the substrate W in Step S10, the controller Ctr may acquire information about the substrate W. The information about the substrate W may be acquired by, for example, reading ID information (for example, character strings and two-dimensional codes) formed at the upper surface Wa of the substrate W using a capturer or the like. The information about the substrate W may be acquired by, for example, storing the ID information of the substrate W in a storage of the carrier 7 in which the substrate W is accommodated and reading the ID information from the storage. The ID information may be, for example, information indicating whether or not the substrate W includes the stacked film 110 constituted with the polysilicon film 111 and the metal film 112 stacked adjacent to the polysilicon film 111.

When the substrate W is determined to include the stacked film 110 based on the information about the substrate W, the controller Ctr may execute the processing of Steps S10 to S13. In this case, by acquiring the information about the substrate W in advance, whether or not the supply of the hydrogen-dissolved chemical liquid L1 and the hydrogen water L2 to the substrate W is required is determined. Therefore, the hydrogen-dissolved chemical liquid L1 and the hydrogen water L2 are supplied only to the substrate W that requires the hydrogen-dissolved chemical liquid L1. This reduces unnecessary consumption of the hydrogen water L2, which makes it possible to suppress the cost of the substrate processing.

When the substrate W is determined to not include the stacked film 110 based on the information about the substrate W, the controller Ctr may instruct the valve V1 to be open while the rotation of the substrate W is continued and the valve V2 remains closed. Thus, the chemical liquid is supplied from the supply unit 41 to the upper surface Wa of the substrate W, so that the substrate W is processed with the chemical liquid. Next, the controller Ctr instructs the valve V4 to be open while the rotation of the substrate W is continued. Thus, the cleaning liquid L3 is supplied from the supply unit 61 to the upper surface Wa of the substrate W, so that the substrate W is cleaned. Next, the controller Ctr instructs the rotary holder 30 to continuously rotate the substrate W for a predetermined period of time. Thus, the drying of the substrate W is performed. In this way, when it is determined that the substrate W does not include the stacked film 110, the substrate W may be processed by using the chemical liquid and the cleaning liquid L3 without having to use the hydrogen-dissolved chemical liquid L1 and the hydrogen water L2.

When the substrate W is determined to include the stacked film 110 based on the information about the substrate W, the controller Ctr may dummy-dispense the hydrogen-dissolved chemical liquid L1 before executing Step S10. Specifically, the controller Ctr instructs the drive 43 to position the nozzle N1 above the liquid receiver 80. Next, the controller Ctr instructs the valves V1 and V2 to be open. Thus, the hydrogen-dissolved chemical liquid L1 is discharged (dummy-dispensed) into the liquid receiver 80 before being supplied to the upper surface Wa of the substrate W. In this case, the hydrogen-dissolved chemical liquid L1, which remains in the pipe D1 and has the decreased concentration of hydrogen, is discharged in advance by the dummy dispense. Therefore, the hydrogen-dissolved chemical liquid L1 having a higher energy level than the metal film 112 is appropriately supplied to the substrate W. Accordingly, it becomes possible to further suppress the corrosion of the polysilicon film 111.

When the substrate W is determined to include the stacked film 110 based on the information about the substrate W, the controller Ctr may dummy-dispense the hydrogen water L2 before executing Step S11. Specifically, the controller Ctr instructs the drive 52 to position the nozzle N2 above the liquid receiver 80. Next, the controller Ctr instructs the valve V3 to be open. Thus, the hydrogen water L2 is discharged (dummy-dispensed) into the liquid receiver 80 before being supplied to the upper surface Wa of the substrate W. In this case, the hydrogen water L2, which remains in the pipe D1 and has the decreased concentration of hydrogen, is discharged in advance by the dummy dispense. Thus, in the case in which the hydrogen water L2 is supplied to the hydrogen-dissolved chemical liquid L1 remaining on the upper surface Wa of the substrate W in Step S11, when the hydrogen-dissolved chemical liquid L1 and the hydrogen water L2 are mixed with each other on the upper surface Wa of the substrate W, the concentration of hydrogen in the resulting mixed liquid hardly decreases. Accordingly, the energy level of the mixed liquid is less likely to be lower than the energy level of the metal film 112. Therefore, the hydrogen-dissolved chemical liquid L1 remaining on the upper surface Wa of the substrate W is washed away by the hydrogen water L2 while the oxidation of silicon by the mixed liquid is suppressed. From the foregoing, it becomes possible to further suppress the corrosion of the polysilicon film 111.

In the above-described example, the hydrogen-dissolved chemical liquid L1 is generated by mixing the chemical liquid supplied from the supply unit 41 with the hydrogen water L2 supplied from the supply unit 42. However, the hydrogen-dissolved chemical liquid L1 may be generated by directly mixing a hydrogen gas with the chemical liquid. Examples of a method of directly mixing the hydrogen gas with the chemical liquid may include a method of mixing the hydrogen gas with the chemical liquid in a bubbling manner and a method of mixing the hydrogen gas with the chemical liquid using an injector.

### EXPERIMENTAL EXAMPLES

The present disclosure will be described in more detail with Example and Comparative

Example, but is not limited thereto.

### EXAMPLE

A chip was prepared by singulating a substrate, on which a stacked film constituted with a polysilicon film, titanium nitride, tungsten, and titanium nitride was patterned on a silicon wafer, into pieces having a size of 20 mm×20 mm. Next, a hydrogen-dissolved chemical liquid was prepared by mixing hydrofluoric acid and hydrogen water (having a dissolved hydrogen concentration of 1.6 ppm) at a ratio of 1:360 (a dilute hydrofluoric acid liquid in which hydrogen is dissolved was obtained the mixing of the hydrofluoric acid with the hydrogen water), and the chip was immersed in the hydrogen-dissolved chemical liquid for 12 seconds. Next, the chip was immersed in the hydrogen water (having a dissolved hydrogen concentration of 1.6 ppm) for 15 seconds. Next, the chip was immersed in isopropyl alcohol (IPA) for 20 seconds. Next, air was blown toward the chip to dry the chip.

Next, a line width of a silicon wafer side (bottom) and a line width of a titanium nitride side (top) of the polysilicon film in the chip were measured, respectively, and a difference between these line widths (top/bottom difference) was calculated.

### COMPARATIVE EXAMPLE

A chip was prepared by singulating a substrate, on which a stacked film constituted with a polysilicon film, titanium nitride, tungsten, and titanium nitride was patterned on a silicon wafer, into pieces having a size of 20 mm×20 mm. Next, a dilute hydrofluoric acid liquid was prepared by mixing hydrofluoric acid and pure water (DIW) at a ratio of 1:360, and the chip was immersed in the dilute hydrofluoric acid for 12 seconds. Next, the chip was immersed in the pure water (DIW) for 15 seconds. Next, the chip was immersed in isopropyl alcohol (IPA) for 20 seconds. Next, air was blown toward the chip to dry the chip.

Next, a line width of the silicon wafer side (bottom) and a line width of the titanium nitride side (top) of the polysilicon film in the chip were measured, respectively, and a difference between these line widths (top/bottom difference) was calculated.

### Results

In Example, the top/bottom difference was at least 0.8. In most patterns, the top/bottom difference was significantly greater than 0.8. In contrast, in Comparative Example, the top/bottom difference was approximately 0.7. Therefore, it was confirmed that, according to Example, the corrosion of the polysilicon film can be suppressed.

### OTHER EXAMPLES

### Example 1

An example of the substrate processing method includes: a first process of supplying, to a substrate including a stacked film constituted with a polysilicon film and a metal film stacked adjacent to the polysilicon film, a hydrogen-dissolved chemical liquid in which hydrogen is dissolved in a chemical liquid, wherein an energy level of the hydrogen-dissolved chemical liquid is higher than that of the metal film; and a second process of supplying hydrogen water to the substrate after the first process.

According to the method of Example 1, the hydrogen-dissolved chemical liquid, in which hydrogen is dissolved in the chemical liquid and which has a higher energy level than the metal film, is supplied to the substrate. In this case, electrons that have moved from a conduction band of silicon to the metal film are less likely to move to the hydrogen-dissolved chemical liquid. Therefore, electrons that are not consumed in the reduction of hydrogen ions return to a valence band of silicon. Accordingly, the oxidation of silicon is less likely to occur.

Further, according to the method of Example 1, the hydrogen water is supplied to the substrate after the first process. In this case, the hydrogen water is supplied to the hydrogen-dissolved chemical liquid remaining on the upper surface of the substrate. Thus, when the hydrogen-dissolved chemical liquid and the hydrogen water are mixed with each other on the surface of the substrate, a concentration of hydrogen in a resulting mixed liquid is less likely to decrease. Therefore, an energy level of the mixed liquid is less likely to be lower than that of the metal film. Accordingly, the hydrogen-dissolved chemical liquid remaining on the upper surface of the substrate is washed away by the hydrogen water while the oxidation of silicon by the mixed liquid is suppressed.

From the foregoing, it becomes possible to suppress the corrosion of the polysilicon film.

### Example 2

In the method of Example 1 above, the concentration of hydrogen in the hydrogen-dissolved chemical liquid may be 1 ppm or more. In this case, the energy level of the hydrogen-dissolved chemical liquid tends to be higher than that of the metal film. Therefore, it becomes possible to further suppress the corrosion of the polysilicon film.

### Example 3

In the method of Example 1 or 2 above, the concentration of hydrogen in the hydrogen-dissolved chemical liquid may be a saturation concentration. In this case, the energy level of the hydrogen-dissolved chemical liquid tends to be further higher than that of the metal film. Therefore, it becomes possible to further suppress the corrosion of the polysilicon film.

### Example 4

The method of any one of Examples 1 to 3 above may further include a third process of supplying a cleaning liquid to the substrate after the second process. In this case, after the hydrogen-dissolved chemical liquid is washed away by the hydrogen water, the cleaning liquid is supplied to the substrate. Therefore, the cleaning liquid is supplied to the upper surface of the substrate in a state where no hydrogen-dissolved chemical liquid almost remains on the upper surface of the substrate. Thus, even if the cleaning liquid and the hydrogen water are mixed with each other on the upper surface of the substrate and the concentration of hydrogen in the resulting mixed liquid decreases, the oxidation of silicon hardly occurs. Accordingly, it becomes possible to suppress the polysilicon film from corroding due to the supply of the cleaning liquid to the substrate. In addition, since the substrate is cleaned by the cleaning liquid, an amount of the hydrogen water supplied in the second process may be set to a level sufficient to wash away the hydrogen-dissolved chemical liquid remaining on the upper surface of the substrate. Therefore, unnecessary consumption of the hydrogen water may be reduced, which makes it possible to suppress the cost of substrate processing.

### Example 5

The method of any one of Examples 1 to 4 above may further include a fourth process of determining whether or not the substrate includes the stacked film based on information about the substrate before the first process. when it is determined in the fourth process that the substrate includes the stacked film, the first process and the second process are executed. In this case, by acquiring the information about the substrate in advance, whether or not the supply of the hydrogen-dissolved chemical liquid and the hydrogen water to the substrate is required is determined. Therefore, the hydrogen-dissolved chemical liquid and the hydrogen water are supplied only to the substrate that requires the hydrogen-dissolved chemical liquid. Accordingly, unnecessary consumption of the hydrogen water may be reduced, which makes it possible to suppress the cost of substrate processing.

### Example 6

In the method of Example 5 above, when it is determined in the fourth process that the substrate includes the stacked film, the first process may include supplying the hydrogen water from a hydrogen water source and the chemical liquid from a chemical liquid source, respectively, and mixing the hydrogen water with the chemical liquid to generate the hydrogen-dissolved chemical liquid, and then supplying the hydrogen-dissolved chemical liquid to the substrate. In this case, the hydrogen water is mixed with the chemical liquid immediately before the hydrogen-dissolved chemical liquid is supplied to the substrate that requires the hydrogen-dissolved chemical liquid. Therefore, the concentration of hydrogen in the hydrogen-dissolved chemical liquid hardly decreases until the hydrogen-dissolved chemical liquid is supplied to the substrate. Accordingly, it becomes possible to further suppress the corrosion of polysilicon film.

### Example 7

The method of Example 5 or 6 above may further include, when it is determined in the fourth process that the substrate includes the stacked film, a fifth process of dummy-dispensing the hydrogen-dissolved chemical liquid before the first process. In this case, the hydrogen-dissolved chemical liquid, which remains in the pipe D1 and has the decreased concentration of hydrogen, is discharged in advance by the dummy dispense. Therefore, the hydrogen-dissolved chemical liquid having a higher energy level than the metal film is appropriately supplied to the substrate. Accordingly, it becomes possible to further suppress the corrosion of the polysilicon film.

### Example 8

An example of a substrate processing apparatus may include: a rotary holder configured to hold and rotate a substrate including a stacked film constituted with a polysilicon film and a metal film stacked adjacent to the polysilicon film; a first supplier configured to supply, to an upper surface of the substrate held by the rotary holder, a hydrogen-dissolved chemical liquid in which hydrogen is dissolved in a chemical liquid; a second supplier configured to supply hydrogen water to the upper surface of the substrate held by the rotary holder; and a controller, wherein the controller may be configured to execute: a first process of controlling the first supplier to supply the hydrogen-dissolved chemical liquid to the upper surface of the substrate held by the rotary holder; and a second process of controlling the second supplier to supply the hydrogen water to the upper surface of the substrate held by the rotary holder after the first process. In this case, the same effects as those of the method of Example 1 above are obtained.

### Example 9

In the apparatus of Example 8 above, a concentration of hydrogen in the hydrogen-dissolved chemical liquid may be 1 ppm or more. In this case, the same effects as those of the method of Example 2 above are obtained.

### Example 10

In the apparatus of Example 8 or 9 above, the concentration of hydrogen in the hydrogen-dissolved chemical liquid may be a saturation concentration. In this case, the same effects as those of the method of Example 3 above are obtained.

### Example 11

The apparatus of any one of Examples 8 to 10 above may further include a third supplier configured to supply a cleaning liquid to the upper surface of the substrate held by the rotary holder, wherein the controller may be configured to further execute, after the second process, a third process of controlling the third supplier to supply the cleaning liquid to the upper surface of the substrate held by the rotary holder. In this case, the same effects as those of the method of Example 4 above are obtained.

### Example 12

In the apparatus of any one of Examples 8 to 11 above, the controller may be configured to further execute a fourth process of determining whether or not the substrate includes the stacked film based on information about the substrate before the first process. When it is determined in the fourth process that the substrate includes the stacked film, the controller may be configured to execute the first process and the second process. In this case, the same effects as those of the method of Example 5 above are obtained.

### Example 13

In the apparatus of Example 12 above, the first supplier may include a source of the hydrogen water and a source of the chemical liquid. When it is determined in the fourth process that the substrate includes the stacked film, the first process may include controlling the first supplier to supply the hydrogen water from the hydrogen water source and the chemical liquid from the chemical liquid source, respectively, and mixing the hydrogen water and the chemical liquid to generate the hydrogen-dissolved chemical liquid, and then supplying the hydrogen-dissolved chemical liquid to the substrate. In this case, the same effects as those of the method of Example 6 above are obtained.

### Example 14

In the apparatus of Example 12 or 13 above, when it is determined in the fourth process that the substrate includes the stacked film, the controller may be configured to further execute a fifth process of controlling the first supplier to dummy-dispense the hydrogen-dissolved chemical liquid before the first process. In this case, the same effects as those of the method of Example 7 above are obtained.

According to a substrate processing method and substrate processing apparatus of the present disclosure, it becomes possible to suppress corrosion of a polysilicon film.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing method comprising:
a first process of supplying, to a substrate including a stacked film constituted by a polysilicon film and a metal film stacked adjacent to the polysilicon film, a hydrogen-dissolved chemical liquid in which hydrogen is dissolved in a chemical liquid, wherein an energy level of the hydrogen-dissolved chemical liquid is higher than an energy level of the metal film; and
a second process of supplying hydrogen water to the substrate after the first process.

2. The substrate processing method of claim 1, wherein a concentration of the hydrogen in the hydrogen-dissolved chemical liquid is 1 ppm or more.

3. The substrate processing method of claim 1, wherein a concentration of the hydrogen in the hydrogen-dissolved chemical liquid is a saturation concentration.

4. The substrate processing method of claim 1, further comprising: a third process of supplying a cleaning liquid to the substrate after the second process.

5. The substrate processing method of claim 1, further comprising: a fourth process of determining whether or not the substrate includes the stacked film by acquiring information about the substrate before the first process,
wherein, when the substrate is determined to include the stacked film in the fourth process, the first process and the second process are executed.

6. The substrate processing method of claim 2, further comprising: a fourth process of determining whether or not the substrate includes the stacked film by acquiring information about the substrate before the first process,
wherein, when the substrate is determined to include the stacked film in the fourth process, the first process and the second process are executed.

7. The substrate processing method of claim 5, wherein, when the substrate is determined to include the stacked film in the fourth process, the first process includes: supplying the hydrogen water from a hydrogen-water source and the chemical liquid from a chemical-liquid source, respectively, and mixing the hydrogen water and the chemical liquid to generate the hydrogen-dissolved chemical liquid; and then supplying the hydrogen-dissolved chemical liquid to the substrate.

8. The substrate processing method of claim 5, further comprising: when the substrate is determined to include the stacked film in the fourth process, a fifth process of dummy-dispensing the hydrogen-dissolved chemical liquid before the first process.

9. A substrate processing apparatus comprising:
a rotary holder configured to hold and rotate a substrate including a stacked film constituted by a polysilicon film and a metal film stacked adjacent to the polysilicon film;
a first supplier configured to supply, to an upper surface of the substrate held by the rotary holder, a hydrogen-dissolved chemical liquid in which hydrogen is dissolved in a chemical liquid;
a second supplier configured to supply hydrogen water to the upper surface of the substrate held by the rotary holder; and
a controller,
wherein the controller is configured to execute:
a first process of controlling the first supplier to supply the hydrogen-dissolved chemical liquid to the upper surface of the substrate held by the rotary holder; and
a second process of controlling the second supplier to supply the hydrogen water to the upper surface of the substrate held by the rotary holder after the first process.

10. The substrate processing apparatus of claim 9, wherein a concentration of the hydrogen in the hydrogen-dissolved chemical liquid is 1 ppm or more.

11. The substrate processing apparatus of claim 9, wherein a concentration of the hydrogen in the hydrogen-dissolved chemical liquid is a saturation concentration.

12. The substrate processing apparatus of claim 9, further comprising: a third supplier configured to supply a cleaning liquid to the upper surface of the substrate held by the rotary holder,
wherein the controller is configured to further execute, after the second process, a third process of controlling the third supplier to supply the cleaning liquid to the upper surface of the substrate held by the rotary holder.

13. The substrate processing apparatus of claim 9, wherein the controller is configured to further execute a fourth process of determining whether or not the substrate includes the stacked film by acquiring information about the substrate before the first process, and
wherein, when the substrate is determined to include the stacked film in the fourth process, the controller is configured to execute the first process and the second process.

14. The substrate processing apparatus of claim 10, wherein the controller is configured to further execute a fourth process of determining whether or not the substrate includes the stacked film by acquiring information about the substrate before the first process, and
wherein, when the substrate is determined to include the stacked film in the fourth process, the controller is configured to execute the first process and the second process.

15. The substrate processing apparatus of claim 13, wherein the first supplier includes a hydrogen-water source and a chemical-liquid source, and
wherein, when the substrate is determined to include the stacked film in the fourth process, the first process includes: controlling the first supplier to supply the hydrogen water from the hydrogen-water source and the chemical liquid from the chemical-liquid source, respectively, and mixing the hydrogen water and the chemical liquid to generate the hydrogen-dissolved chemical liquid; and then supplying the hydrogen-dissolved chemical liquid to the substrate.

16. The substrate processing apparatus of claim 13, wherein, when the substrate is determined to include the stacked film in the fourth process, the controller is configured to further execute a fifth process of controlling the first supplier to dummy-dispense the hydrogen-dissolved chemical liquid before the first process.
